(19) United States
(12) Patent Application Publication
(10) Pub. No.: US 2026/0040602 A1
(43) Pub. Date: Feb. 5, 2026

(54) GALLIUM NITRIDE-BASED SEMICONDUCTOR DEVICES WITH DIELECTRIC SEGMENTS AND METHODS OF FABRICATION THEREOF

(71) Applicant: TEXAS INSTRUMENTS INCORPORATED, Dallas, TX (US)

(72) Inventors: Dong Seup Lee, Allen, TX (US); Seongmo Hwang, Garland, TX (US); Jungwoo Joh, Allen, TX (US)

(21) Appl. No.: 18/794,301

(22) Filed: Aug. 5, 2024

(51) Int. Cl. H01L 29/778; H01L 21/02; H01L 23/31; H01L 29/20; H01L 29/40; H01L 29/66

(52) U.S. Cl. CPC H10D 30/475; H01L 21/0217; H01L 21/02271; H01L 23/3171; H10D 30/015; H10D 62/8503; H10D 64/112

(57) ABSTRACT

Semiconductor devices and fabrication methods thereof are described. For example, a semiconductor device includes a GaN heterojunction structure disposed on a substrate. The GaN heterojunction structure includes a barrier layer disposed on a GaN layer. The semiconductor device further includes a source contact, a drain contact, and a gate electrode. The gate electrode is disposed above the GaN heterojunction structure and between the source contact and the drain contact. The semiconductor device still further includes a plurality of segments of dielectric material disposed on the barrier layer between the source contact and the drain contact.

### TECHNICAL FIELD

The present disclosure relates to the field of semiconductor devices, and more particularly, but not exclusively, to gallium nitride-based semiconductor devices (GaN devices).

### BACKGROUND

GaN devices can deliver various characteristics that are superior to silicon-based semiconductor devices. GaN devices typically include a heterojunction structure that induces highly-mobile 2-dimensional electron gas (2DEG) at the interface of two dissimilar semiconductor materials. GaN devices have faster switching speeds than silicon-based semiconductor devices and excellent reverse-recovery performance. GaN devices are suitable for low-loss and high-efficiency performance applications.

### SUMMARY

The present disclosure describes GaN devices with dielectric segments and methods of fabrication thereof. This summary is not an extensive overview of the disclosure. Rather, a purpose of the summary is to present some examples of the present disclosure in a simplified form as a prelude to a more detailed description that is presented later.

In some examples, a semiconductor device includes a GaN heterojunction structure disposed on a substrate. The GaN heterojunction structure includes a barrier layer disposed on a GaN layer. The semiconductor device further includes a source contact, a drain contact, and a gate electrode. The gate electrode is disposed above the GaN heterojunction structure and between the source contact and the drain contact. The semiconductor device still further includes a plurality of segments of dielectric material disposed on the barrier layer between the source contact and the drain contact.

In some other examples, a semiconductor device includes a GaN heterojunction structure disposed on a substrate. The GaN heterojunction structure includes a barrier layer disposed on a GaN layer. The semiconductor device further includes a source contact, a drain contact, and a gate electrode. The gate electrode is disposed above the GaN heterojunction structure and between the source contact and the drain contact. The semiconductor device still further includes a first silicon nitride layer including a first segment and a second segment. The first segment and the second segment are disposed on the barrier layer and separated by a gate region. The semiconductor device also includes a second silicon nitride layer disposed on the first segment and the second segment.

In some additional examples, a method of fabricating a semiconductor device includes forming a GaN heterojunction structure on a substrate. The GaN heterojunction structure includes a barrier layer formed on a GaN layer. The method further includes forming a first dielectric layer on the barrier layer, the first dielectric layer formed using an in-situ dielectric deposition process, and forming a second dielectric layer on the first dielectric layer, the second dielectric layer formed using an ex-situ dielectric deposition process. The method also includes forming a gate electrode above the barrier layer, and forming a source contact and a drain contact on opposite sides of the gate electrode. The first dielectric layer includes a plurality of segments of dielectric material.

### BRIEF DESCRIPTION OF THE DRAWINGS

FIG. 1 is a cross-sectional view of a GaN device with dielectric segments in accordance with an example of the present disclosure;

FIGS. 2A-2F are cross-sectional views of a process flow for forming a GaN device with dielectric segments in accordance with an example of the present disclosure;

FIG. 3 is a cross-sectional view of a GaN device with dielectric segments in accordance with another example of the present disclosure; and

FIGS. 4A-4E are cross-sectional views of a process flow for forming a GaN device with dielectric segments in accordance with another example of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean+/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

GaN devices (e.g., GaN transistors) may be regarded as high electron mobility transistors (HEMTs) in view of a layer of highly-mobile electrons formed in the GaN devices, which may be referred to as a 2-dimensional electron gas (2DEG) or a 2DEG layer. The 2DEG can be formed at an interface of a heterojunction structure having two dissimilar semiconductor materials in contact with each other. For example, a layer of a group-III nitride-based alloy material (e.g., aluminum gallium nitride (AlGaN)) can be formed (e.g., epitaxially grown) on another layer of a group-III nitride material (e.g., gallium nitride (GaN)) to form a heterojunction structure. Conduction-band offset between the two semiconductor materials and/or polarization discontinuity present in such a heterojunction structure can induce the 2DEG at its interface—e.g., at the surface of the GaN layer in contact with the AlGaN layer.

The phenomenon of inducing/forming the 2DEG at the interface of the heterojunction structure may be modeled as: (i) forming a sheet of fixed positive charges at the interface of the heterojunction structure; and (ii) accumulating electrons at the interface to compensate the positive charges at the interface. Although some of the description herein focuses on heterojunction structures including a GaN-based alloy layer (e.g., AlGaN layer) and a GaN layer for illustration purposes, the present disclosure is not limited thereto. For example, methods described herein can be applied to other heterojunction structures that can induce the 2DEG at their interface.

GaN devices include 2DEG formed between source and drain contacts of the GaN devices—e.g., 2DEG formed at the surface of a GaN layer in contact with an AlGaN layer, which provides a channel for current conduction between the source and drain contacts. As such, the channel between the source and drain contacts may be referred to as a surface channel or a device channel. Moreover, a gate electrode is positioned between the source and drain contacts to control the current conduction. The GaN devices can be configured as enhancement-mode GaN devices (e-mode GaN devices) or depletion-mode GaN devices (d-mode GaN devices). The e-mode GaN devices are configured to have electrons of the 2DEG depleted (absent) under the gate electrode resulting in normally-OFF devices. The e-mode GaN devices can be turned ON by applying a positive voltage to the gate contact structure. On the other hand, the d-mode GaN devices are configured to have the 2DEG present under the gate electrode resulting in normally-ON devices. The d-mode GaN devices can be turned OFF by applying a negative voltage to the gate electrode.

During high-voltage operations (e.g., switching operations turning the GaN devices ON or OFF with a drain bias voltage being greater than 100V, 200V, 300V, or even greater), the electrons may get trapped at various sites located at or in the vicinity of the channel of a GaN device. The trapping sites may be present within a dielectric passivation layer (e.g., a silicon nitride layer) formed on the AlGaN layer, at the interface between the AlGaN layer and the dielectric passivation layer, at various crystallographic defect sites that may be present within the GaN layer, among others. The trapped electrons may reduce the electron concentration in the channel (e.g., 2DEG density), which in turn may increase the resistance of the channel between the source and drain (e.g., dynamic RDS_ON) when the GaN device is turned ON. In some cases, the dynamic RDS_ON can increase approximately 50% or greater after certain high-voltage operations, resulting in dynamic RDS_ON stability issues. Such RDS_ON stability issues thus impact the specific on-resistance RSP of the GaN device, since RSP=RDS_ON×device area. Accordingly, 2DEG density impacts RDS_ON and RSP stability.

Moreover, 2DEG density is affected by the composition of the AlGaN layer (e.g., also referred to as a barrier layer). Increasing the percent composition of Al in the AlGaN layer tends to increase 2DEG density, while decreasing the Al percent composition has the opposite effect on 2DEG density. Still further, when a silicon nitride layer, such as the above-mentioned dielectric passivation layer, is uniformly formed on the AlGaN layer using an in-situ dielectric deposition process, 2DEG density increases uniformly across the 2DEG layer. An in-situ deposition process can include depositing the silicon nitride layer on the GaN heterojunction structure in a vacuum chamber without breaking vacuum following the epitaxial growth of the GaN heterojunction structure. Uniform deposition here refers to the in-situ silicon nitride layer fully extending across the AlGaN layer between the source contact and the drain contact. The 2DEG density increase achieved with a uniformly deposited in-situ silicon nitride layer can be due to a change in surface fermi-level pinning, among other causes. In such instances, 2DEG density can then be controlled by increasing or decreasing the Al percent composition in the AlGaN layer. However, while increasing 2DEG density may lower the RSP and improve the dynamic RDS_ON, excessively high 2DEG density may degrade the time-dependent dielectric breakdown (TDDB) lifetime of the GaN device, as well as negatively impact the threshold voltage (Vt).

To address the above and other technical challenges in GaN and other semiconductor device designs, examples of the present disclosure describe semiconductor devices with GaN heterostructure structures, and methods for fabricating the same, that provide local control of 2DEG density by the selective formation of dielectric segments on the AlGaN layer between the source contact and the drain contact of the GaN device.

For example, a semiconductor device may include a GaN heterojunction structure disposed on a substrate, wherein the GaN heterojunction structure includes a barrier layer (e.g., AlGaN layer) disposed on a GaN layer. The semiconductor device may also include a source contact, a drain contact, and a gate electrode, wherein the gate electrode is disposed above the GaN heterojunction structure and between the source contact and the drain contact. The semiconductor device may further include a plurality of segments of dielectric material disposed on the barrier layer between the source contact and the drain contact.

As will be further described below, forming the plurality of segments of dielectric material (e.g., in-situ silicon nitride (SiN)) at select locations along the top surface of the barrier layer between the source contact and the drain contact enables local control of 2DEG density along the device channel. In other words, 2DEG density can be locally modulated (varied, controlled) in view of presence of the dielectric material or lack thereof along the device channel. For example, a first segment of the plurality of segments can be disposed adjacent to the source contact and a second segment of the plurality of segments can be disposed adjacent to the drain contact. As a result, 2DEG density is relatively higher near the source and drain contacts.

Likewise, forming one or more additional segments of the plurality of segments of dielectric material between the gate electrode and the second segment, with one or more openings disposed between one or more pairs of the plurality of segments, enables relatively lower 2DEG density in the device channel locations corresponding to the one or more openings where high electric field may otherwise develop. For example, the semiconductor device can include one or more field plates disposed above the gate electrode, extending toward the drain contact, and respectively terminating at one or more edges. In some examples, relatively high electric field may develop between the one or more edges of the field plates and the corresponding device channel locations. In some examples, the one or more field plates are connected to the source contact. The one or more openings disposed in the layer of dielectric material can be arranged such that the one or more edges of the one or more field plates respectively terminate above the one or more openings. Having openings at these locations below the field plate edges results in relatively lower 2DEG density in the 2DEG layer corresponding to these locations, which in turn ameliorate high electric field at these locations so as to avoid deleterious effects of the high electric field.

In some examples, a dielectric layer (e.g., SiN) can be formed on the plurality of segments of dielectric material using an ex-situ dielectric deposition process (e.g., formed absent the vacuum used to form in-situ silicon nitride, formed outside the chamber used to form the heterojunction structure and the in-situ silicon nitride).

In some other examples, the barrier layer includes one of: aluminum (Al) and GaN (AlGaN); indium (In), Al, and N (InAlN); In, Al, and GaN (InAlGaN); and Al and N (AlN).

In some additional examples, a semiconductor device includes a GaN heterojunction structure disposed on a substrate, wherein the GaN heterojunction structure includes a barrier layer disposed on a GaN layer. The semiconductor device also includes a source contact, a drain contact, and a gate electrode, wherein the gate electrode is disposed above the GaN heterojunction structure and between the source contact and the drain contact. The semiconductor device still further includes: (i) a first silicon nitride layer including a first segment and a second segment, the first segment and the second segment being disposed on the barrier layer and separated by a gate region; and (ii) a second silicon nitride layer disposed on the first segment and the second segment. The first segment may extend between a source region and the gate region and the second segment may extend between the gate region and a drain region of the semiconductor device.

In some additional examples, a method of fabricating a semiconductor device includes forming: (i) GaN heterojunction structure on a substrate, the GaN heterojunction structure including a barrier layer formed on a GaN layer; (ii) forming a first dielectric layer on the barrier layer, the first dielectric layer formed using an in-situ dielectric deposition process; (iii) forming a second dielectric layer on the first dielectric layer, the second dielectric layer formed using an ex-situ dielectric deposition process; (iv) forming a gate electrode above the barrier layer; and (v) forming a source contact and a drain contact on opposite sides of the gate electrode; wherein the first dielectric layer comprises a plurality of segments of dielectric material.

In some examples, the plurality of segments of the first dielectric layer are formed before the forming of the second dielectric layer, while in other examples the plurality of segments of the first dielectric layer are formed after the forming of the second dielectric layer.

Further, in some examples, the forming of the GaN heterojunction structure may include epitaxially growing at least a portion of the GaN heterojunction structure in a vacuum chamber. The forming of the first dielectric layer may include depositing silicon nitride on the GaN heterojunction structure in the vacuum chamber without breaking vacuum following epitaxially growing at least the portion of the GaN heterojunction structure. The depositing of the silicon nitride on the GaN heterojunction structure may utilize a metalorganic chemical vapor deposition (MOCVD) process. The forming of the second dielectric layer may include depositing silicon nitride on the first dielectric layer using a low pressure CVD (LPCVD) process. In some examples, formation of the plurality of segments is performed separately from formation of a gate region including the gate electrode.

Still further, in some examples, the method may include forming one or more field plates above the gate electrode, the one or more field plates extending toward the drain contact and respectively terminating at one or more edges. In some examples, the one or more field plates connect to the source contact. The one or more edges may respectively terminate above one or more openings disposed between one or more pairs of the plurality of segments. At least a portion of the one or more openings over which the one or more edges terminate may be formed between the gate electrode and the drain contact.

Additionally, in some examples, prior to forming the gate electrode, the method may include forming a third dielectric layer (e.g., a gate dielectric layer), wherein the forming of the third dielectric layer includes: (i) etching at least the second dielectric layer to form a trench, the trench including opposing sidewalls and a bottom that exposes the barrier layer; and (ii) depositing the third dielectric layer over the second dielectric layer, over the sidewalls of the trench, and over the exposed barrier layer. The gate electrode may be formed over the third dielectric layer with a first portion of the gate electrode being inside the trench and a second portion of the gate electrode being outside the trench and overlapping a portion of the second dielectric layer.

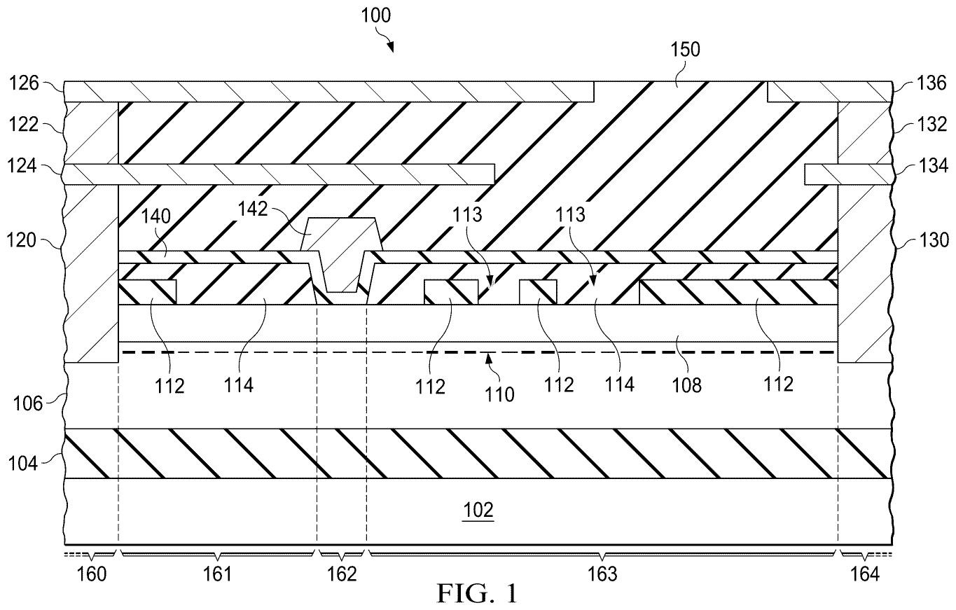

Referring now to FIG. 1, a cross-sectional view of a GaN device 100 with dielectric segments is depicted in accordance with an example of the present disclosure. GaN device 100 is an example of a d-mode GaN device. As mentioned, a d-mode GaN device is configured to have 2DEG present under a gate electrode resulting in a normally-ON device, such that the d-mode GaN device can be turned OFF by applying a negative voltage to the gate electrode.

As shown, GaN device 100 includes a substrate 102, a buffer layer 104, a GaN layer 106, and a barrier layer (e.g., AlGaN layer) 108. The GaN layer 106 and the barrier layer 108 are collectively referred to as a GaN heterojunction structure.

In some examples, the substrate 102 may be a bulk semiconductor substrate, a semiconductor-on-insulator (SOI) substrate, or any other suitable substrate. For example, the substrate 102 may be or include a bulk silicon wafer. The buffer layer 104 (also referred to as a transition layer) may include any number of layers of any materials that are configured to accommodate lattice mismatch between the substrate 102 and the GaN layer 106 (e.g., to reduce or minimize lattice defect generation and/or propagation in the GaN layer 106). For example, the buffer layer 104 may have a gradient concentration of one or more elements in a direction normal to the upper surface of the substrate 102. Further, the buffer layer 104 may include at least one doped layer.

The GaN layer 106 is configured, in conjunction with the barrier layer 108, to conduct and confine charge carriers (such as electrons) within two dimensions. More particularly, the GaN layer 106 is configured to include a 2DEG layer 110. The 2DEG layer 110 is induced at or near the surface of the GaN layer 106, which is in contact with the barrier layer 108, by conduction-band offset between the two semiconductor materials (e.g., GaN and AlGaN) and/or polarization discontinuity present in the heterojunction structure formed by the GaN layer 106 and the barrier layer 108.

In some examples, the GaN layer 106 may be a portion of a semiconductor substrate (e.g., without buffer layer 104), and/or the substrate 102 with the buffer layer 104 and the GaN layer 106 may be considered a semiconductor substrate. In some examples, the GaN layer 106 may be referred to as a GaN channel layer. In some examples, the material of the GaN layer 106 is or includes an unintentionally doped material, such as a material doped by diffusion of dopants from another layer, or is or includes an intrinsic material. The barrier layer 108, in some examples, may be or include an aluminum gallium nitride (AlGaN) layer and, in such examples, may be referred to as an AlGaN barrier layer. In some examples, the GaN layer 106 may be or include indium aluminum gallium nitride (InᵢAlⱼGa₁₋ᵢ₋ⱼN) (e.g., where 0≤i≤1, 0≤j≤1, and 0≤i+j≤1), and the barrier layer 108 may be or include indium aluminum gallium nitride (InₖAlₗGa₁₋ₖ₋ₗN) (e.g., where 0≤k≤1, 0≤l≤1, and 0≤k+l≤1). Other materials may be implemented for the GaN layer 106 and/or the barrier layer 108.

GaN device 100 also includes a plurality of segments of dielectric material 112, which may also be referred to as a first dielectric layer 112, disposed on the barrier layer 108. While GaN device 100 in FIG. 1 illustrates four segments of dielectric material 112, other examples may include less segments while still other examples include more segments. Further, GaN device 100 includes a second dielectric layer 114 over the first dielectric layer 112. A source contact 120 extends through the barrier layer 108 and into the GaN layer 106 contacting the 2DEG layer 110 on a first side, while a drain contact 130 extends through the barrier layer 108 and into the GaN layer 106 contacting the 2DEG layer 110 on a second side. A source field plate structure, including a field plate support 122 and first and second field plates 124 and 126, is connected to the source contact 120. A drain field plate structure, including a field plate support 132 and first and second field plates 134 and 136, is connected to the drain contact 130.

Further, a gate dielectric layer 140 is disposed on the second dielectric layer 114 with a trench portion extending through and contacting with the barrier layer 108. A gate electrode 142 is disposed on the gate dielectric layer 140 with a first portion of the gate electrode 142 being inside the trench portion of the gate dielectric layer 140 and a second portion of the gate electrode 142 being outside the trench portion and overlapping the gate dielectric layer 140 on opposite sides of the gate electrode 142.

A dielectric layer 150 is disposed on the gate dielectric layer 140 and the gate electrode 142 and between the source contact 120 and the source field plate structure (e.g., including the field plate support 122 and the first and second field plates 124 and 126) and the drain contact 130 and the drain field plate structure (e.g., including the field plate support 132 and the first and second field plates 134 and 136).

As further shown in FIG. 1 with regard to GaN device 100, a source region 160 is defined by the source contact 120, a source access region 161 is defined between the source contact 120 and the gate electrode 142, a gate region 162 is defined by the gate electrode 142, a drain access region 163 is defined between the gate electrode 142 and the drain contact 130, and a drain region 164 is defined by the drain contact 130.

Not expressly shown in FIG. 1, but understood to be present in GaN device 100, are respective metal contacts (e.g., metal vias and metal interconnects) for the source contact 120, the gate electrode 142, and the drain contact 130. GaN device 100 can have additional layers and/or structures that are not expressly shown in FIG. 1 such as, but not limited to, conductive layers, additional dielectric layers, and/or additional field plate structures.

In some examples, the source contact 120, the drain contact 130, and the gate electrode 142 may be or include a metal, such as titanium nitride (TiN), tantalum nitride (TaN), titanium (Ti), aluminum (Al), copper (Cu), tungsten (W), the like, or a combination thereof. The respective field plate structures connected to the source contact 120 and the drain contact 130 may be or include the same or similar metals as the metals mentioned above, as well as different metals. Still further, the gate dielectric layer 140, in some examples, may be or include an oxide-based dielectric such as aluminum oxide (Al₂O₃), hafnium oxide (HfO₂), and the like, although nitride-base dielectrics can also be used in other examples.

The dielectric layer 150, which may be an inter-layer dielectric layer (ILD), may be a single dielectric layer or may include multiple dielectric layers of a same dielectric material or different dielectric materials. For example, the dielectric layer 150 may include silicon nitride, a silicon oxide-based material (such as a phosphosilicate glass (PSG) or a tetraethyl orthosilicate (TEOS) oxide), polytetrafluoroethylene, or the like.

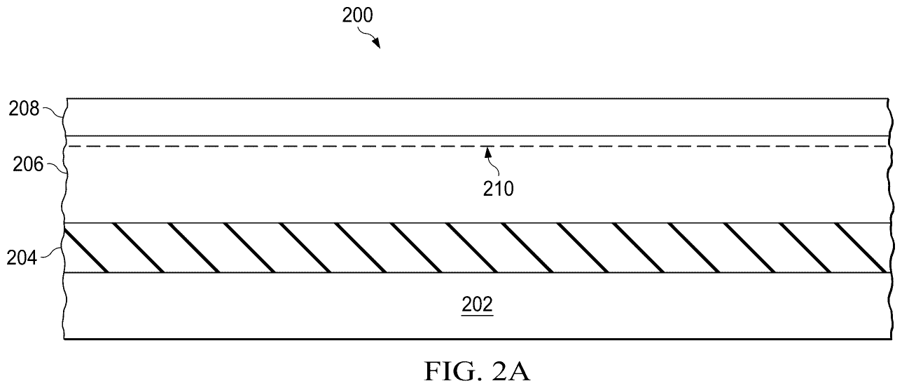

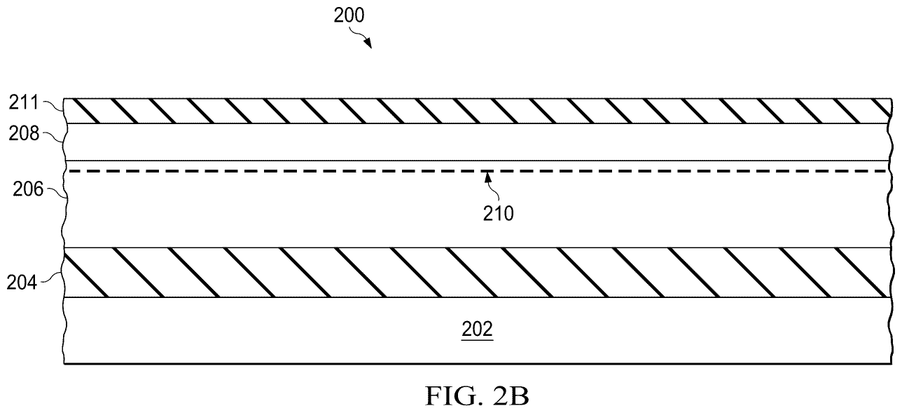

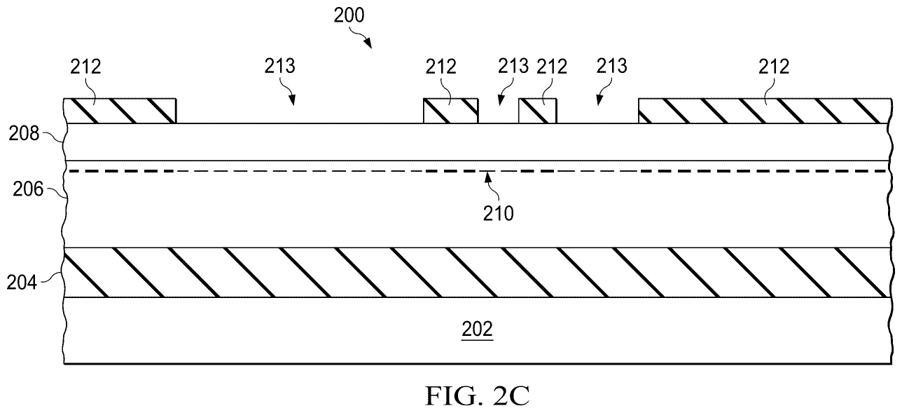

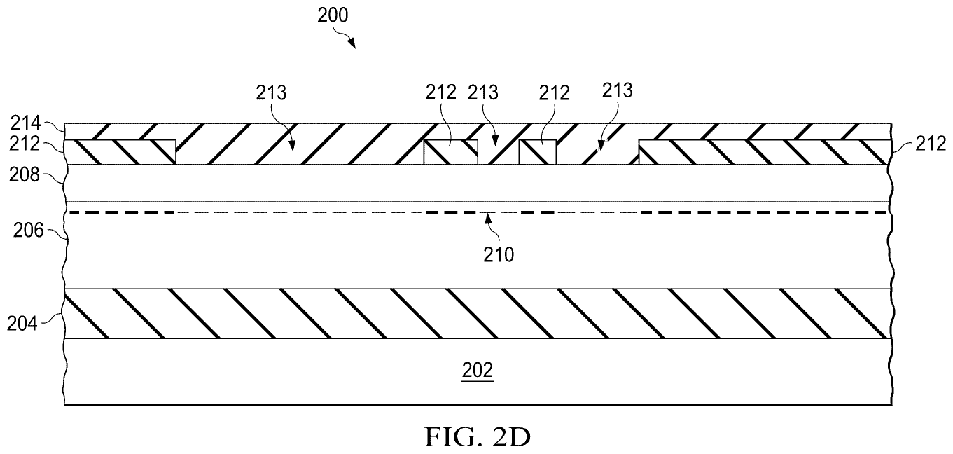

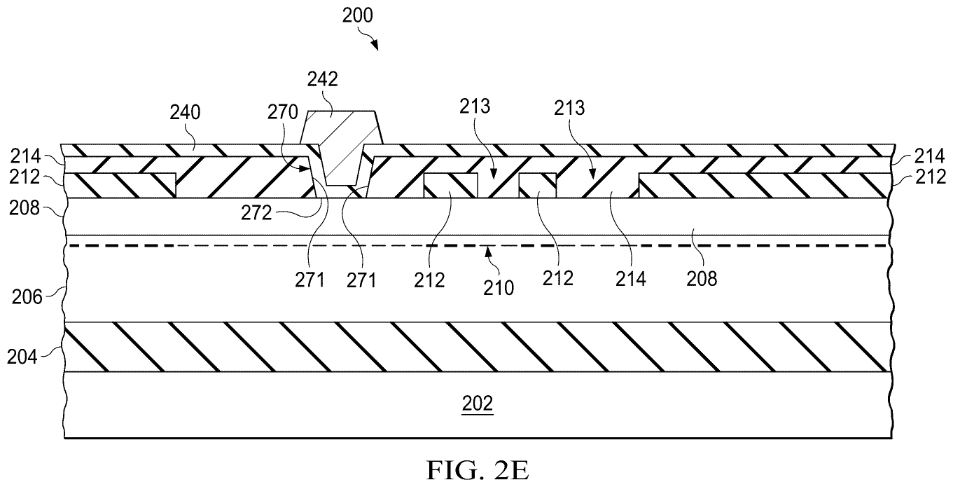

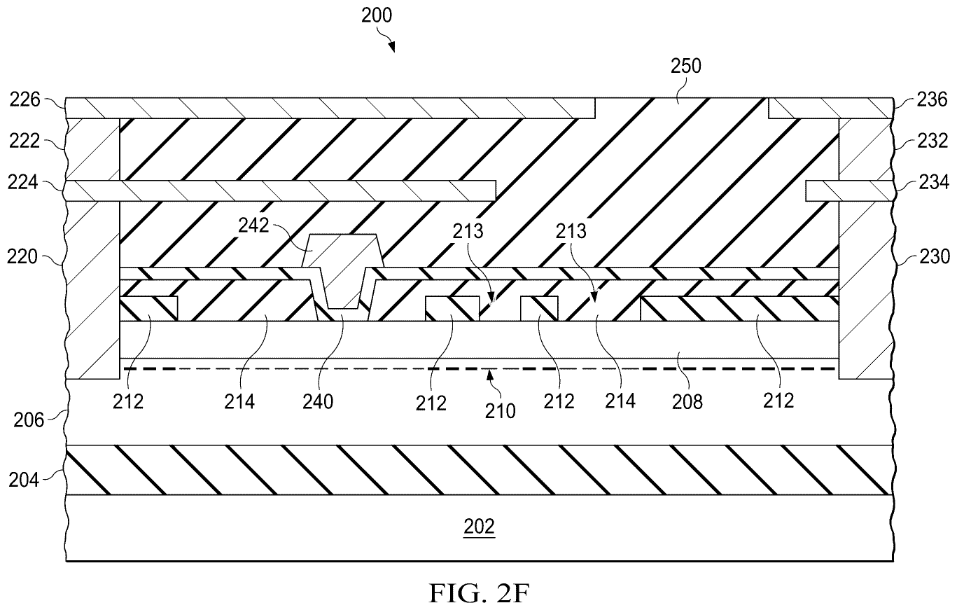

Returning now to the plurality of segments of dielectric material 112 (e.g., the first dielectric layer 112) and the second dielectric layer 114, in some examples, both dielectric layers may be or include SiN or some other dielectric material. However, as will be further described below in the context of FIGS. 2A through 2F, the plurality of segments of dielectric material 112 are formed using an in-situ dielectric deposition process, while the second dielectric layer 114 is formed using an ex-situ dielectric deposition process.

As shown, the plurality of segments of dielectric material 112 are selectively located along the top surface of the barrier layer 108 between the source contact 120 and the drain contact 130. In accordance with examples of the present disclosure, the location of the plurality of segments of dielectric material 112 enables local control of the 2DEG density of the 2DEG layer 110. The 2DEG layer 110 is represented at or near the top surface of the GaN layer 106 as a dashed line extending between the source contact 120 and the drain contact 130 having dashes with varying thickness (e.g., two thickness). More particularly, thin dashed lines represent relatively lower 2DEG density and thick dashed lines represent relatively higher 2DEG density. Accordingly, 2DEG density of the 2DEG layer 110 below each segment of the plurality of segments of the dielectric material 112 is relatively higher as compared to the 2DEG density of the 2DEG layer 110 below the openings between pairs of segments of the plurality of segments of the dielectric material 112.

In some examples, 2DEG density (ns) can range from about (or below) 1×10¹² cm⁻² to about 2×10¹³ cm⁻². Further, in some examples, a difference between the higher 2DEG density regions (e.g., regions represented as the thick dashes below the segments of dielectric material 112) and the lower 2DEG density regions (e.g., regions represented as the thin dashes below the openings between the segments of dielectric material 112) can range between about 1×10¹² cm⁻² to about 5×10¹² cm⁻². However, in other examples, the 2DEG density difference between the higher 2DEG regions and the lower 2DEG regions can have other ranges depending on factors including, for example, the composition of the epitaxially grown heterojunction structure as well as fabrication processes used.

Thus, as shown, a first segment of the plurality of segments of dielectric material 112 is disposed adjacent to the source contact 120 and a second segment of the plurality of segments of dielectric material 112 disposed adjacent to the drain contact 130. As a result, 2DEG density of the 2DEG layer 110 is relatively higher adjacent to the source and drain contacts 120 and 130. Likewise, additional segments (e.g., two in the example illustrated in FIG. 1) of the plurality of segments of dielectric material 112 may be disposed between the gate electrode 142 and the second segment adjacent the drain contact 130 with openings 113 disposed between one or more pairs of the plurality of segments. 2DEG density is relatively higher in the 2DEG layer 110 below the additional segments, while relatively lower below the openings 113 between the segments. Placement of the openings 113 below the edges of the source field plates 124 and 126 enables relatively lower 2DEG density in high electric field regions, e.g., under the edges at which the source field plates 124 and 126 terminate. In some examples, either the first segment adjacent to the source contact 120 or the second segment adjacent to the drain contact 130 may be omitted.

Referring now to FIGS. 2A-2F, cross-sectional views are shown of a process flow for forming a semiconductor structure 200 with dielectric segments in accordance with an example of the present disclosure. More particularly, the process flow of FIGS. 2A-2F for the semiconductor structure 200 may represent an example of the formation of GaN device 100 in FIG. 1. Accordingly, reference numerals in the 200s in FIGS. 2A-2F correspond to the same layers and structures with reference numerals in the 100s in FIG. 1 (e.g., substrate 202 in FIGS. 2A-2F corresponds to substrate 102 in FIG. 1, buffer layer 204 corresponds to buffer layer 104, and so on).

FIG. 2A depicts formation of a substrate 202, a buffer layer 204, a GaN layer 206, a barrier layer (e.g., AlGaN layer) 208, and a 2DEG layer 210 induced at or near a top surface of the GaN layer 206. More particularly, the buffer layer 204 is formed on substrate 202. The GaN layer 206 is formed on the buffer layer 204. The barrier layer 208 is formed on the GaN layer 206. The 2DEG layer 210 is induced as described above. The buffer layer 204, the GaN layer 206, and the barrier layer 208 are formed by using any suitable deposition process which, in some examples, may be an epitaxial growth process. For example, the buffer layer 204, the GaN layer 206, and the barrier layer 208 may each be epitaxially grown using MOCVD, molecular beam epitaxy (MBE), or another epitaxy process. The materials of the substrate 202, the buffer layer 204, the GaN layer 206, and the barrier layer 208 may include materials as described above in various examples.

FIG. 2B depicts formation of a dielectric layer 211 on the barrier layer 208, while FIG. 2C depicts formation of a plurality of segments of dielectric material 212 from the dielectric layer 211. In some examples, the dielectric layer 211 includes SiN, although one or more other dielectric materials can be used alone or in combination with SiN in other examples. In some examples, the plurality of segments of dielectric material 212 (e.g., SiN segments or alternatively SiN islands) are formed from the dielectric layer 211 using a mask (not expressly shown) to pattern the dielectric layer 211 which is then etched to form the plurality of segments of dielectric material 212 with openings 213 formed therebetween. Etching may include any suitable etch process, e.g., a reactive ion etch (RIE).

As described above, in some examples, the dielectric layer 211 and the plurality of segments of dielectric material 212 are formed using an in-situ dielectric deposition process. Such an in-situ deposition process can include depositing the dielectric layer 211 on the barrier layer 208 in the same vacuum chamber in which the GaN heterojunction structure (e.g., the GaN layer 206 and the barrier layer 208) was previously epitaxially grown. In such an example, dielectric layer 211 and the plurality of segments of dielectric material 212 are formed in the vacuum chamber without breaking vacuum.

For example, after the barrier layer 208 (e.g., AlGaN layer) deposition step (FIG. 2A), Al and Ga source gases are turned off, and the chamber condition is transitioned and configured for deposition of the dielectric material (e.g., SiN) of dielectric layer 211. Subsequently, the plurality of segments of dielectric material 212 may be formed by patterning and etching the dielectric layer 211.

In some other examples, the dielectric layer 211 can be formed under vacuum while the patterning and etching steps to form the plurality of segments of dielectric material 212 and opening 213 can be performed in the absence of vacuum—e.g., using different equipment than the chamber forming the dielectric layer 211.

An in-situ process for forming the dielectric layer 211 and the plurality of segments of dielectric material 212 has many technical advantages. By way of example, an in-situ dielectric deposition process results in a high quality dielectric, wherein surface traps are reduced when grown at a relatively high temperature by MOCVD. As compared to MOCVD, other dielectric deposition processes such as LPCVD may introduce additional process-related defects. Among other technical advantages, an in-situ grown dielectric provides relatively high surface passivation for the barrier layer 208 against air, chemicals, plasma, or additional potential reactants that can adversely modify surface state conditions and add defects to the barrier layer 208. Also, an in-situ grown dielectric can effectively reduce the relaxation of the barrier layer 208 (e.g., during a cool down process) enhancing 2DEG density and thus channel conductivity. Still further, an in-situ grown dielectric, such as SiN, are sensitive to growth conditions such as growth pressure, temperature, and N/Si ratio which determine the SiN material quality, deposition rate, interface trap density, and leakage current. Such growth conditions can be more readily controlled using an in-situ dielectric deposition process.

In some examples, an in-situ dielectric deposition process uses silicon tetrahydride or silane (SiH₄) and anhydrous ammonia (NH₃) as precursor gases in the vacuum chamber and includes the following process ranges: (i) chamber pressure of about 50-600 millibars (mbar), a wafer (substrate) temperature of about 900-1100 degrees Celsius (C), an N/Si ratio of about 0.1-10, and a resulting thickness of the dielectric layer 211 and thus the plurality of segments of dielectric material 212 (as measured from a top surface of the barrier layer 208 to a top surface of the plurality of segments of dielectric material 212) of about 1-10 nanometers (nm). In one example, the segments may have a thickness of about 3-5 nm.

FIG. 2D depicts formation of another dielectric layer 214 on the plurality of segments of dielectric material 212. In some examples, the dielectric layer 214 includes SiN. In some examples, the dielectric layer 214 is a passivation layer. Unlike formation of the plurality of segments of dielectric material 212 using an in-situ dielectric deposition process, in some examples, the dielectric layer 214 can be deposited using an ex-situ dielectric deposition process, e.g., a deposition process outside of a vacuum condition (or in a chamber or equipment different than the chamber used for forming the dielectric layer 211) such as LPCVD.

FIG. 2E depicts formation of a gate dielectric layer 240 and a gate electrode 242. Prior to forming the gate electrode 242, the gate dielectric layer 240 is formed on the dielectric layer 214. In some examples, a mask (not expressly shown and separate from the mask used to pattern the plurality of segments of dielectric material 212) is used to pattern the dielectric layer 214 which is then etched to form a gate trench 270 including opposing sidewalls 271 and a bottom 272 that exposes a portion of the barrier layer 208. Etching may include any suitable etch process, e.g., a reactive ion etch (RIE). The gate dielectric layer 240 is then deposited over the dielectric layer 214, over the sidewalls 271 of the gate trench 270, and over the exposed portion of the barrier layer 208. The gate electrode 242 is then formed with a first portion of the gate electrode 242 inside the gate trench 270 and a second portion of the gate electrode 242 outside the trench overlapping the dielectric layer 214 on opposing sides. Other suitable processes for forming a d-mode type gate electrode, such as the gate electrode 242, can be used in other examples. The materials of the gate dielectric layer 240 and the gate electrode 242 may include materials as described above in various examples.

FIG. 2F depicts formation of a source contact 220, a source field gate structure including a field plate support 222 and first and second field plates 224 and 226, a drain contact 230, a drain field plate structure including a field plate support 232 and first and second field plates 234 and 236, and a dielectric layer 250.

In some examples, after a portion of the dielectric layer 250 (e.g., a portion of the dielectric layer 250 corresponding to the height of the source and drain contacts 220, 230) is deposited (e.g., using one of the ex-situ dielectric deposition processes described in examples above), source and drain contact openings (not expressly shown), respectively for the source contact 220 and the drain contact 230, are formed through the portion of the dielectric layer 250, the gate dielectric layer 240, the dielectric layer 214, and the barrier layer 208, and partially through the GaN layer 206. In some examples, the source and drain contact openings can be formed through any portions of segments of dielectric material 212 that are formed in the intended locations of the source and drain contacts 220 and 230. The source and drain contact openings may be formed using suitable patterning and etching processes, e.g., patterning and etching processes described above. Following formation of the source and drain contact openings, the source contact 220 and the drain contact 230 are respectively formed therein. Any suitable processes for forming metal type source and drain contacts for a GaN device can be used. The materials of the source contact 220 and the drain contact 230 may include materials as described above in various examples.

As further shown in FIG. 2F, the source field plate structure (connected to the source contact 220), including the field plate support 222 and the first and second field plates 224 and 226, and the drain field plate structure (connected to the drain contact 230), including the field plate support 232 and the first and second field plates 234 and 236, are formed in the other portion of the dielectric layer 250—e.g., based on forming one or more dielectric layers and forming one or more conductive structures. The materials of the source field plate structure and the drain field plate structure may include materials as described above in various examples.

Not expressly shown in FIG. 2F, but understood to be present in the semiconductor structure 200, are respective metal contacts (e.g., metal vias and metal interconnects) for the source contact 220, the gate electrode 242, and the drain contact 230. The semiconductor structure 200 can have additional layers and/or structures that are not expressly shown in FIGS. 2A-2F such as, but not limited to, conductive layers, additional dielectric layers, and/or additional field plate structures.

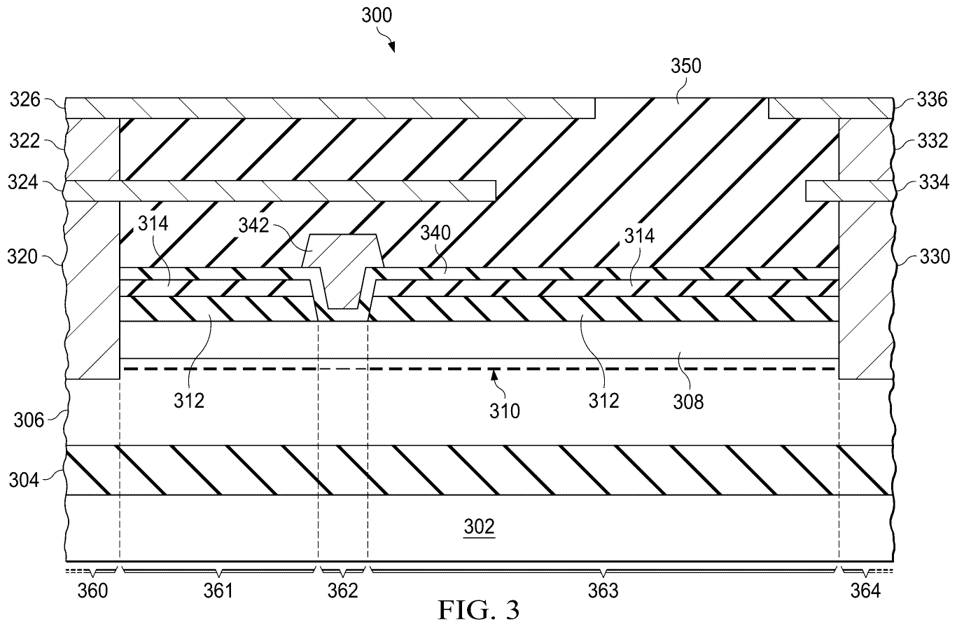

Referring now to FIG. 3, a cross-sectional view of a GaN device 300 with dielectric segments is depicted in accordance with an example of the present disclosure. Similar to GaN device 100 in FIG. 1, GaN device 300 is an example of a d-mode GaN device, e.g., a normally-ON device wherein the device can be turned OFF by applying a negative voltage to a gate electrode.

As shown, GaN device 300 includes a substrate 302, a buffer layer 304, a GaN layer 306, and a barrier layer (e.g., AlGaN layer) 308. The GaN layer 306 and the barrier layer 308 are collectively referred to as a GaN heterojunction structure.

In some examples, the substrate 302 may be a bulk semiconductor substrate, a semiconductor-on-insulator (SOI) substrate, or any other suitable substrate. For example, the substrate 302 may be or include a bulk silicon wafer. The buffer layer 304 (also referred to as a transition layer) may include any number of layers of any materials that are configured to accommodate lattice mismatch between the substrate 302 and the GaN layer 306 (e.g., to reduce or minimize lattice defect generation and/or propagation in the GaN layer 306). For example, the buffer layer 304 may have a gradient concentration of one or more elements in a direction normal to the upper surface of the substrate 302. Further, the buffer layer 304 may include at least one doped layer.

The GaN layer 306 is configured, in conjunction with the barrier layer 308, to conduct and confine charge carriers (such as electrons) within two dimensions. More particularly, the GaN layer 306 is configured to include a 2DEG layer 310. The 2DEG layer 310 is induced at or near the surface of the GaN layer 306, which is in contact with the barrier layer 308, by conduction-band offset between the two semiconductor materials (e.g., GaN and AlGaN) and/or polarization discontinuity present in the heterojunction structure formed by the GaN layer 306 and the barrier layer 308.

In some examples, the GaN layer 306 may be a portion of a semiconductor substrate (e.g., without buffer layer 304), and/or the substrate 302 with the buffer layer 304 and the GaN layer 306 may be considered a semiconductor substrate. In some examples, the GaN layer 306 may be referred to as a GaN channel layer. In some examples, the material of the GaN layer 306 is or includes an unintentionally doped material, such as a material doped by diffusion of dopants from another layer, or is or includes an intrinsic material. The barrier layer 308, in some examples, may be or include an aluminum gallium nitride (AlGaN) layer and, in such examples, may be referred to as an AlGaN barrier layer. In some examples, the GaN layer 306 may be or include indium aluminum gallium nitride (InᵢAlⱼGa₁₋ᵢ₋ⱼN) (e.g., where 0≤i≤1, 0<j≤1, and 0≤i+j≤1), and the barrier layer 308 may be or include indium aluminum gallium nitride (InₖAl/Ga₁₋ₖ₋ₗN) (e.g., where 0≤k≤1, 0≤l≤1, and 0≤k+l≤1). Other materials may be implemented for the GaN layer 306 and/or the barrier layer 308.

GaN device 300 also includes a plurality of segments of dielectric material 312, which may also be referred to as a first dielectric layer 312, disposed on the barrier layer 308. GaN device 300 in FIG. 3 illustrates two segments of dielectric material 312—e.g., a first segment of dielectric material 312 disposed between a source region and a gate region, and a second segment of dielectric material 312 disposed between the gate region and a drain region (e.g., as will be further described below). Thus, the first and second segments of dielectric material 312 are separated by an opening defined by the gate region. Other examples may include less segments while still other examples may include more segments.

Further, GaN device 300 includes a second dielectric layer 314 formed over the first and second segments of dielectric material 312. The second dielectric layer 314 may be considered as having a first segment and a second segment respectively corresponding to the first and second segments of dielectric material 312. A source contact 320 extends through the barrier layer 308 and into the GaN layer 306 contacting the 2DEG layer 310 on a first side, while a drain contact 330 extends through the barrier layer 308 and into the GaN layer 306 contacting the 2DEG layer 310 on a second side. A source field plate structure, including a field plate support 322 and first and second field plates 324 and 326, is connected to the source contact 320. A drain field plate structure, including a field plate support 332 and first and second field plates 334 and 336, is connected to the drain contact 330.

Further, a gate dielectric layer 340 is disposed on the second dielectric layer 314 with a trench portion extending through the second dielectric layer 314 and the first dielectric layer 312, and contacting with the barrier layer 308. A gate electrode 342 is disposed on the gate dielectric layer 340 with a first portion of the gate electrode 342 being inside the trench portion of the gate dielectric layer 340 and a second portion of the gate electrode 342 being outside the trench portion and overlapping the gate dielectric layer 340 on opposite sides of the gate electrode 342.

A dielectric layer 350 is disposed on the gate dielectric layer 340 and the gate electrode 342 and between the source contact 320 and the source field plate structure (e.g., including the field plate support 322 and the first and second field plates 324 and 326) and the drain contact 330 and the drain field plate structure (e.g., including the field plate support 332 and the first and second field plates 334 and 336).

As further shown in FIG. 3 with regard to GaN device 300, a source region 360 is defined by the source contact 320, a source access region 361 is defined between the source contact 320 and the gate electrode 342, a gate region 362 is defined by the gate electrode 342, a drain access region 363 is defined between the gate electrode 342 and the drain contact 330, and a drain region 364 is defined by the drain contact 330.

Not expressly shown in FIG. 3, but understood to be present in GaN device 300, are respective metal contacts (e.g., metal vias and metal interconnects) for the source contact 320, the gate electrode 342, and the drain contact 330. GaN device 300 can have additional layers and/or structures that are not expressly shown in FIG. 3 such as, but not limited to, conductive layers, additional dielectric layers, and/or additional field plate structures.

In some examples, the source contact 320, the drain contact 330, and the gate electrode 342 may be or include a metal, such as titanium nitride (TiN), tantalum nitride (TaN), titanium (Ti), aluminum (Al), copper (Cu), tungsten (W), the like, or a combination thereof. The respective field plate structures connected to the source contact 320 and the drain contact 330 may be or include the same or similar metals as the metals mentioned above, as well as different metals. Still further, the gate dielectric layer 340, in some examples, may be or include an oxide-based dielectric such as aluminum oxide (Al₂O₃), hafnium oxide (HfO₂), and the like, although nitride-base dielectrics can also be used in other examples.

The dielectric layer 350, which may be an inter-layer dielectric layer (ILD), may be a single dielectric layer or may include multiple dielectric layers of a same dielectric material or different dielectric materials. For example, the dielectric layer 150 may include silicon nitride, a silicon oxide-based material (such as a phosphosilicate glass (PSG) or a tetraethyl orthosilicate (TEOS) oxide), polytetrafluoroethylene, or the like.

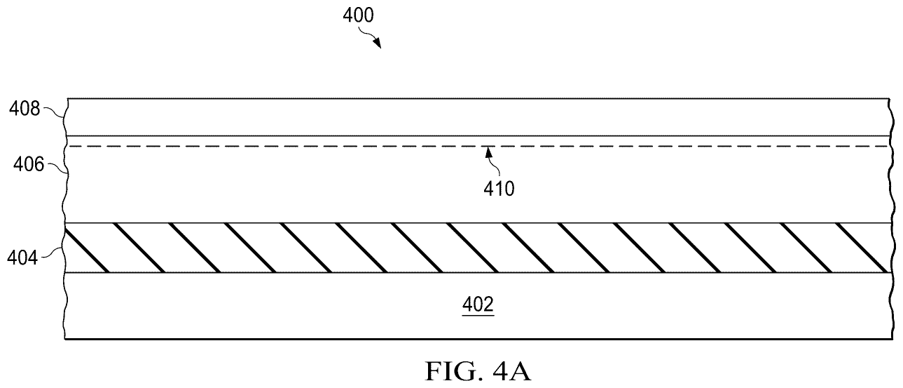

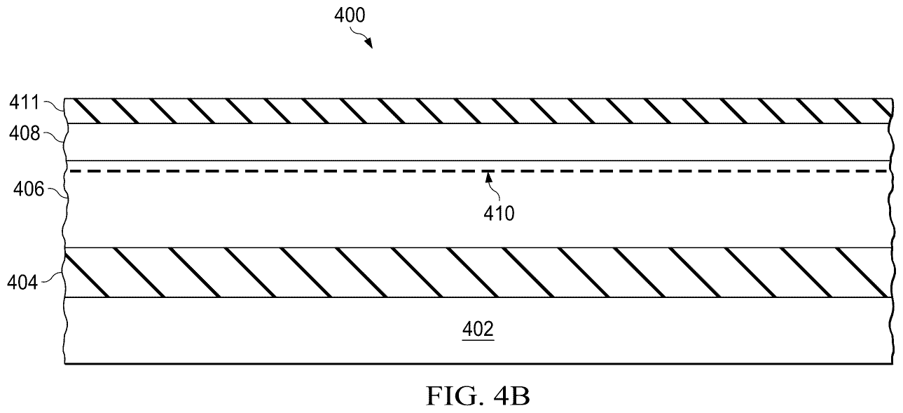

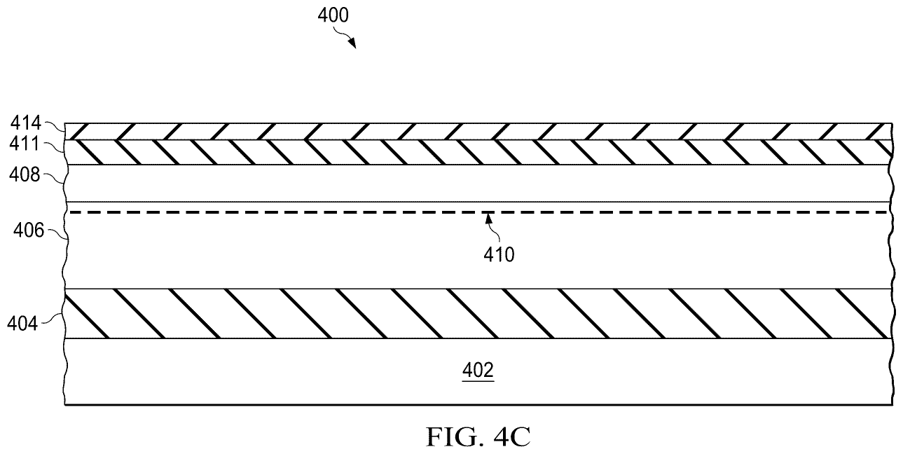

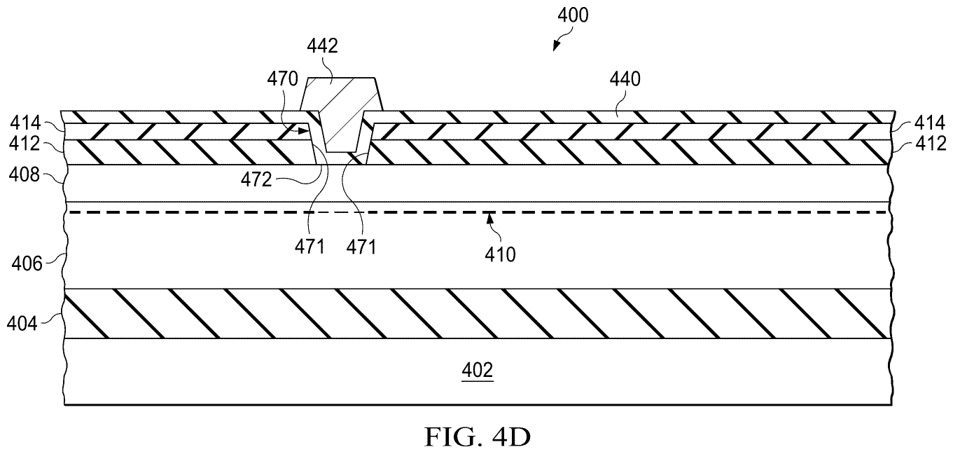

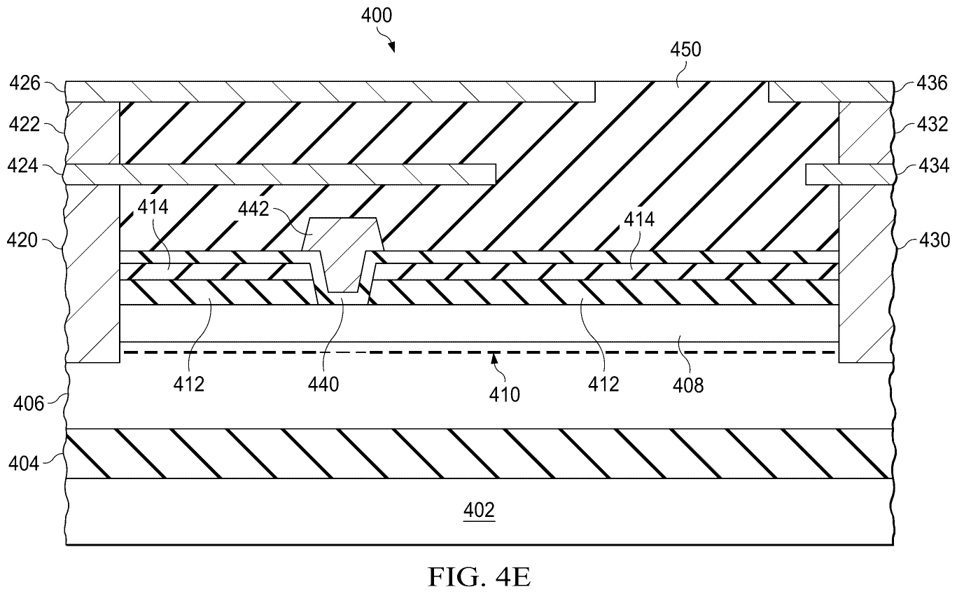

Returning now to the first and second segments of dielectric material 312 and the second dielectric layer 314, in some examples, both may be or include SiN or some other dielectric material. However, as will be further described below in the context of FIGS. 4A through 4E, a dielectric material (from which the first and second segments of dielectric material 312 are formed) is deposited using an in-situ dielectric deposition process, while the second dielectric layer 314 is formed using an ex-situ dielectric deposition process.

As shown, the first and second segments of dielectric material 312 are selectively located along the top surface of the barrier layer 308—e.g., the first segment between the source contact 320 and one side of the gate region 362 (e.g., the source access region 361) and the second segment between the other side of the gate region 362 and the drain contact 330 (e.g., the drain access region). In accordance with examples of the present disclosure, the location of the first and second segments of dielectric material 312 enables local control of the density of the 2DEG layer 310. The 2DEG layer 310 is represented at or near the top surface of the GaN layer 306 as a dashed line extending between the source contact 320 and the drain contact 330 having dashes with varying thickness (e.g., two thickness). More particularly, thin dashed lines represent relatively lower 2DEG density and thick dashed lines represent relatively higher 2DEG density. Accordingly, 2DEG density of the 2DEG layer 310 below the first and second segments of the dielectric material 312 is relatively higher as compared to the 2DEG density of the 2DEG layer 310 below the opening between the first and second segments (e.g., occupied by parts of the gate dielectric layer 340 and the gate electrode 342).

In some examples, 2DEG density (ns) can range from about (or below) 1×10¹² cm⁻² to about 2×10¹³ cm⁻². Further, in some examples, a difference between the higher 2DEG density regions (e.g., regions represented as the thick dashes below the first and second segments of dielectric material 312) and the lower 2DEG density regions (e.g., the region represented as the thin dashes below the opening between the first and second segments of dielectric material 312) can range between about 1×10¹² cm⁻² to about 5×10¹² cm⁻². However, in other examples, the 2DEG density difference between the higher 2DEG regions and the lower 2DEG regions can have other ranges depending on factors including, for example, the composition of the epitaxially grown heterojunction structure as well as fabrication processes used.

Referring now to FIGS. 4A-4E, cross-sectional views are shown of a process flow for forming a semiconductor structure 400 with dielectric segments in accordance with an example of the present disclosure. More particularly, the process flow of FIGS. 4A-4E for the semiconductor structure 400 may represent an example of the formation of GaN device 300 in FIG. 3. Accordingly, reference numerals in the 400s in FIGS. 4A-4E correspond to the same layers and structures with reference numerals in the 300s in FIG. 3 (e.g., substrate 402 in FIGS. 4A-4E corresponds to substrate 302 in FIG. 3, buffer layer 404 corresponds to buffer layer 304, and so on).

FIG. 4A depicts formation of a substrate 402, a buffer layer 404, a GaN layer 406, a barrier layer (e.g., AlGaN layer) 408, and a 2DEG layer 410 induced at or near a top surface of the GaN layer 406. More particularly, the buffer layer 404 is formed on substrate 402. The GaN layer 406 is formed on the buffer layer 404. The barrier layer 408 is formed on the GaN layer 406. The 2DEG layer 410 is induced as described above. The buffer layer 404, the GaN layer 406, and the barrier layer 408 are formed by using any suitable deposition process which, in some examples, may be an epitaxial growth process. For example, the buffer layer 404, the GaN layer 406, and the barrier layer 408 may each be epitaxially grown using MOCVD, molecular beam epitaxy (MBE), or another epitaxy process. The materials of the substrate 402, the buffer layer 404, the GaN layer 406, and the barrier layer 408 may include materials as described above in various examples.

FIG. 4B depicts formation of a dielectric layer 411 on the barrier layer 408. In some examples, the dielectric layer 411 includes SiN, although one or more other dielectric materials can be used alone or in combination with SiN in other examples. The dielectric layer 411 is the dielectric layer from which first and second dielectric segments of dielectric material 412 (FIG. 4D) will be formed.

Dielectric layer 411, in some examples, is formed using an in-situ dielectric deposition process. Such an in-situ deposition process can include depositing the dielectric layer 411 on the barrier layer 408 in the same vacuum chamber in which the GaN heterojunction structure (e.g., the GaN layer 406 and the barrier layer 408) was previously epitaxially grown. In such an example, dielectric layer 411 is formed in the vacuum chamber without breaking vacuum.

For example, after the barrier layer 408 (e.g., AlGaN layer) deposition step (FIG. 4A), Al and Ga source gases are turned off, and the chamber condition is transitioned and configured for deposition of the dielectric material (e.g., SiN) of the dielectric layer 411. One or more of the technical advantages described above with respect to the process flow of FIGS. 2A-2F when using an in-situ process for forming dielectric layer (e.g., dielectric layer 411) apply to the process flow of FIGS. 4A-4E. Further, the in-situ dielectric deposition process used to form the dielectric layer 411 can use the same or similar precursor gases in the vacuum chamber and can have the same or similar process ranges as in the process flow of FIGS. 2A-2F.

FIG. 4C depicts formation of another dielectric layer 414 on the dielectric layer 411. In some examples, the dielectric layer 414 includes SiN. In some examples, the dielectric layer 414 is a passivation layer. Unlike formation of the dielectric layer 411 using an in-situ dielectric deposition process, in some examples, the dielectric layer 414 can be deposited using an ex-situ dielectric deposition process, e.g., a deposition process outside of a vacuum condition, using different equipment than the chamber forming the dielectric layer 411. For example, dielectric layer 414 can be deposited using LPCVD.

FIG. 4D depicts formation of a gate dielectric layer 440 and a gate electrode 442. Prior to forming the gate electrode 442, the gate dielectric layer 440 is formed on the dielectric layer 414. In some examples, a mask (not expressly shown) is used to pattern the dielectric layers 411 and 414 which are then etched to form a gate trench 470 including opposing sidewalls 471 and a bottom 472 that exposes a portion of the barrier layer 408. Etching may include any suitable etch process, e.g., a reactive ion etch (RIE). The gate dielectric layer 440 is then deposited over the dielectric layer 414, over the sidewalls 471 of the gate trench 470, and over the exposed portion of the barrier layer 408. The gate electrode 442 is then formed with a first portion of the gate electrode 442 inside the gate trench 470 and a second portion of the gate electrode 442 outside the trench overlapping the dielectric layer 414 on opposing sides. Other suitable processes for forming a d-mode type gate electrode, such as the gate electrode 442, can be used in other examples. The materials of the gate dielectric layer 440 and the gate electrode 442 may include materials as described above in various examples.

During the patterning and etching steps that result in the formation of gate trench 470, the dielectric layer 411 is separated into first and second segments of dielectric material 412—e.g., the first and second segments separated by parts of the gate dielectric layer 440 and the gate electrode 442. As such, the in-situ deposited dielectric material of the dielectric layer 411 is removed under the gate electrode 442 (e.g., a gate region as described above). Thus, advantageously, the first and second segments of dielectric material 412 are formed with the same mask used to form the gate trench 470 through the dielectric layer 414.

FIG. 4E depicts formation of a source contact 420, a source field gate structure including a field plate support 422 and first and second field plates 424 and 426, a drain contact 430, a drain field plate structure including a field plate support 432 and first and second field plates 434 and 436, and a dielectric layer 450.

In some examples, after a portion of the dielectric layer 450 (e.g., a portion of the dielectric layer 450 corresponding to the height of the source and drain contacts 420, 430) is deposited (e.g., using one of the ex-situ dielectric deposition processes described in examples above), source and drain contact openings (not expressly shown), respectively for the source contact 420 and the drain contact 430, are formed through the portion of the dielectric layer 450, the gate dielectric layer 440, the dielectric layer 414, and the barrier layer 408, and partially through the GaN layer 406. In some examples, the source and drain contact openings can be formed through any portions of first and second segments of dielectric material 412 that are formed in the intended locations of the source and drain contacts 420 and 430. The source and drain contact openings may be formed using suitable patterning and etching processes, e.g., patterning and etching processes described above. Following formation of the source and drain contact openings, the source contact 420 and the drain contact 430 are respectively formed therein. Any suitable processes for forming metal type source and drain contacts for a GaN device can be used. The materials of the source contact 420 and the drain contact 430 may include materials as described above in various examples.

As further shown in FIG. 4E, the source field plate structure (connected to the source contact 420), including the field plate support 422 and the first and second field plates 424 and 426, and the drain field plate structure (connected to the drain contact 430), including the field plate support 432 and the first and second field plates 434 and 436, are formed in the other portion of the dielectric layer 450—e.g., based on forming one or more dielectric layers and forming one or more conductive structures. The materials of the source field plate structure and the drain field plate structure may include materials as described above in various examples.

Not expressly shown in FIG. 4E, but understood to be present in the semiconductor structure 400, are respective metal contacts (e.g., metal vias and metal interconnects) for the source contact 420, the gate electrode 442, and the drain contact 430. The semiconductor structure 400 can have additional layers and/or structures that are not expressly shown in FIGS. 4A-4E such as, but not limited to, conductive layers, additional dielectric layers, and/or additional field plate structures.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a gallium nitride (GaN) heterojunction structure disposed on a substrate, the GaN heterojunction structure including a barrier layer disposed on a GaN layer;
a source contact, a drain contact, and a gate electrode, the gate electrode disposed above the GaN heterojunction structure and between the source contact and the drain contact; and
a plurality of segments of dielectric material disposed on the barrier layer between the source contact and the drain contact.

2. The semiconductor device of claim 1, wherein a first segment of the plurality of segments is disposed adjacent to the source contact and a second segment of the plurality of segments is disposed adjacent to the drain contact.

3. The semiconductor device of claim 2, wherein one or more additional segments of the plurality of segments of dielectric material are disposed between the gate electrode and the second segment.

4. The semiconductor device of claim 1, further comprising:
one or more field plates disposed above the gate electrode, extending toward the drain contact, and respectively terminating at one or more edges.

5. The semiconductor device of claim 4, wherein the one or more field plates are connected to the source contact.

6. The semiconductor device of claim 4, wherein the one or more edges of the one or more field plates respectively terminate above one or more openings disposed between one or more pairs of the plurality of segments.

7. The semiconductor device of claim 6, wherein at least a portion of the one or more openings over which the one or more edges terminate are disposed between the gate electrode and the drain contact.

8. The semiconductor device of claim 1, wherein the plurality of segments of dielectric material comprise silicon nitride.

9. The semiconductor device of claim 1, further comprising a dielectric layer disposed on the plurality of segments of dielectric material.

10. The semiconductor device of claim 9, where the dielectric layer comprises silicon nitride.

11. The semiconductor device of claim 1, wherein the barrier layer comprises one of:
aluminum (Al) and GaN (AlGaN); indium (In), Al, and N (InAlN); In, Al, and GaN (InAlGaN); and Al and N (AlN).

12. A semiconductor device, comprising:
a gallium nitride (GaN) heterojunction structure disposed on a substrate, the GaN heterojunction structure including a barrier layer disposed on a GaN layer;
a source contact, a drain contact, and a gate electrode, the gate electrode disposed above the GaN heterojunction structure and between the source contact and the drain contact;
a first silicon nitride layer including a first segment and a second segment, the first segment and the second segment disposed on the barrier layer and separated by a gate region; and
a second silicon nitride layer disposed on the first segment and the second segment.

13. The semiconductor device of claim 12, wherein the first segment extends between a source region and the gate region and the second segment extends between the gate region and a drain region.

14. A method of fabricating a semiconductor device, comprising:
forming a gallium nitride (GaN) heterojunction structure on a substrate, the GaN heterojunction structure including a barrier layer formed on a GaN layer;
forming a first dielectric layer on the barrier layer, the first dielectric layer formed using an in-situ dielectric deposition process;
forming a second dielectric layer on the first dielectric layer, the second dielectric layer formed using an ex-situ dielectric deposition process;
forming a gate electrode above the barrier layer; and
forming a source contact and a drain contact on opposite sides of the gate electrode;
wherein the first dielectric layer comprises a plurality of segments of dielectric material.

15. The method of claim 14, wherein the plurality of segments of the first dielectric layer are formed before the forming of the second dielectric layer.

16. The method of claim 14, wherein the plurality of segments of the first dielectric layer are formed after the forming of the second dielectric layer.

17. The method of claim 14, wherein the forming of the GaN heterojunction structure includes epitaxially growing at least a portion of the GaN heterojunction structure in a vacuum chamber.

18. The method of claim 17, wherein the forming of the first dielectric layer includes depositing silicon nitride on the GaN heterojunction structure in the vacuum chamber without breaking vacuum following epitaxially growing at least the portion of the GaN heterojunction structure.

19. The method of claim 18, wherein the depositing of the silicon nitride on the GaN heterojunction structure utilizes a metalorganic chemical vapor deposition.

20. The method of claim 18, wherein the forming of the second dielectric layer includes depositing silicon nitride on the first dielectric layer.

21. The method of claim 14, wherein formation of the plurality of segments is performed separate from formation of a gate region including the gate electrode.

22. The method of claim 14, further comprising:
forming one or more field plates above the gate electrode, the one or more field plates extending toward the drain contact and respectively terminating at one or more edges, the one or more field plates connecting to the source contact.

23. The method of claim 22, wherein the one or more edges respectively terminate above one or more openings disposed between one or more pairs of the plurality of segments.

24. The method of claim 23, wherein at least a portion of the one or more openings over which the one or more edges terminate are formed between the gate electrode and the drain contact.

25. The method of claim 14, prior to forming the gate electrode, further comprising forming a third dielectric layer, wherein the forming of the third dielectric layer includes:
etching at least the second dielectric layer to form a trench, the trench including opposing sidewalls and a bottom that exposes the barrier layer; and
depositing the third dielectric layer over the second dielectric layer, over the sidewalls of the trench, and over the exposed barrier layer;
wherein the gate electrode is formed over the third dielectric layer with a first portion of the gate electrode being inside the trench and a second portion of the gate electrode being outside the trench.
